(19) United States
(12) Patent Application Publication
(10) Pub. No.: US 2013/0346831 A1
(43) Pub. Date: Dec. 26, 2013

(54) METHOD OF GENERATING FORWARD ERROR CORRECTION PACKET AND SERVER AND CLIENT APPARATUS EMPLOYING THE SAME

(71) Applicants: Ho Jin Ha, Wonju-si (KR); Chang Hoon Yim, Seoul (KR)

(72) Inventors: Ho Jin Ha, Wonju-si (KR); Chang Hoon Yim, Seoul (KR)

(73) Assignee: INDUSTRIAL COOPERATION FOUNDATION HALLA UNIVERSITY, Gangwon-do (KR)

(21) Appl. No.: 13/585,334

(22) Filed: Aug. 14, 2012

(30) Foreign Application Priority Data
Jun. 21, 2012 (KR) 10-2012-0066602

(51) Int. Cl. H03M 13/05; G06F 11/10

(52) U.S. Cl. 714/776; 714/E11.032

(57) ABSTRACT

Provided are a method of generating a forward error correction (FEC) packet for scalable video streaming and a server and a client apparatus using the same. The method includes generating a plurality of temporal layers (TLs) of which the number is a second number to provide temporal scalability for one group of pictures (GOP) constituted of a plurality of frames of which the number is a first number, allocating FEC data to the TL, and generating a transmission packet by interleaving at least one of the FEC data and video data constituted of at least one frame for the TL. FEC can be performed without receiving all data by allocating FEC data in units of TLs, and hence a delay can be minimized. In addition, there is an advantage in that robustness to burst errors is provided by applying interleaving between video data and FEC data for the TLs.

### BACKGROUND

1. Field of the Invention

The present invention relates to scalable video coding (SVC), and more particularly, to a method of generating a forward error correction (FEC) packet for scalable video streaming and a server and a client apparatus using the same.

2. Discussion of Related Art

Schemes for transmitting a video over a network include a download scheme and a streaming scheme.

As a scheme for receiving and reproducing a given video file pre-downloaded to a computer of a user, the download scheme is not suitable for the concept of transmitting real-time media.

On the other hand, video streaming technology is available in various application fields such as Internet broadcasting because the video streaming technology is based on real-time transmission, which is executed at the moment a user selects media content.

Because video streaming should be performed in real time, the video streaming is sensitive to delay and loss and a minimum bandwidth required for service should be ensured.

However, the Internet based on a current best-effort transmission scheme does not ensure any service quality for video streaming on the Internet. This means that packets are likely to be lost according to a network situation when a video is transmitted over a network in real time. Accordingly, active research has been conducted on a method capable of improving the quality of a video in the network in which packet loss may occur.

Because real-time video streaming is sensitive to delay, there is a need for an error control method capable of maintaining the image quality of a video to the maximum extent possible. Representative technology for processing packet loss includes automatic retransmission request (ARQ) and FEC. ARQ is not suitable for a video streaming service because the number of network transmissions is increased due to retransmission of a lost packet and hence loss is caused by excessive transmission. On the other hand, FEC does not require additional transmission such as retransmission or feedback because a redundant packet is added to restore loss. However, a delay is caused by the redundant packet.

FEC can be performed at a byte level and a packet level. In the byte-level FEC, one symbol is a byte. In the packet-level FEC, one symbol is a packet. In general, the byte-level FEC is performed in a physical layer and a transport layer. On the other hand, the packet-level FEC is mainly used for real-time services or multicasting services because lost packets can be restored without a retransmission request for the lost packet.

In particular, in real-time video application services, the packet-level FEC is mainly used at an application level as in an unequal error protection (UEP) algorithm so as to improve the deterioration of image quality due to packet loss in an end user stage. That is, the image quality is effectively improved by allocating more redundant packets for packets having a large influence on the deterioration of image quality.

The demand for SVC capable of providing various image qualities while adjusting a bit rate is increasing in various channel environments. Recently, standardization for new SVC based on H.264 has been conducted by the International Organization for Standardization/International Electrotechnical Commission (ISO/IEC) Moving Picture Experts Group (MPEG) and the International Telecommunication Union Telecommunication Standardization Sector (ITU-T) Video Coding Expert Group (VCEG). In SVC, it is possible to generate a bit-stream constituted of one base layer and a plurality of higher layers capable of providing temporal, spatial, and quality improvements so as to provide temporal, spatial, and quality scalability. When the entire bit-stream is received, image quality of a highest resolution can be obtained. There is an advantage in that part of the bit-stream can be received and decoded so that various temporal and spatial resolutions can be provided if a channel environment is bad.

However, although an SVC bit-stream can be adapted to various network environments, it is still difficult to perform transmission robust to packet loss under an unstable network situation.

On the other hand, in general, data interleaving technology is widely used to minimize the deterioration of image quality due to packet loss. In the related art, continuous video packets are separated at given intervals, so that the deterioration of the image quality due to the packet loss is scattered or dispersed. However, an application field can be limited because a delay is caused by interleaving.

FIG. 1 illustrates a motion compensated temporal filtering (MCTF) structure for giving temporal scalability and quality scalability in SVC. One group of pictures (GOP) is constituted of 8 frames. Each frame has a temporal layer (TL) and a quality layer (QL). A reproduction frame rate differs according to the TL. FIG. 1 illustrates an example of a hierarchical prediction structure having four TLs.

Referring to FIG. 1, when only TL0 is reproduced, only frames 0, 8, and 16 are reproduced. When TL0 and TL1 are reproduced, frames 0, 4, 8, 16, 32, and the like are reproduced. When TL0, TL1, and TL2 are reproduced, frames 0, 2, 4, 6, 8, 10, 12, 14, 16, . . . are reproduced. When TL0, TL1, TL2, and TL3 are reproduced, continuous video frames 0, 1, 2, 3, 4, 5, . . . are reproduced.

FIG. 2 illustrates a sequence of transmission of scalable video frames based on the MCTF structure illustrated in FIG. 1.

In the structure as described above, an influence on the deterioration of image quality due to packet loss is larger when the TL is lower. This is because the loss of frames belonging to a TL in which frames of TL1 are referred to affects the deterioration of image quality when TL1 is lost.

In addition, a delay occurs, leading to the deterioration of image quality because a receiving stage can perform FEC decoding only when receiving all frames.

### SUMMARY OF THE INVENTION

The present invention is directed to a method of generating an FEC packet and a server and a client apparatus using the same, which can minimize a delay when an FEC packet is decoded in SVC having a hierarchical structure.

According to a first aspect of the present invention, there is provided a method of generating an FEC packet, including: generating a plurality of TLs of which the number is a second number to provide temporal scalability for one GOP constituted of a plurality of frames of which the number is a first number; allocating FEC data to each TL; and generating a transmission packet by interleaving at least one of the FEC data and video data constituted of at least one frame for each TL.

According to a second aspect of the present invention, there is provided a server for providing scalable video streaming, including: an FEC packet generation section configured to generate a transmission packet by generating a plurality of TLs of which the number is a second number to provide temporal scalability for one GOP constituted of a plurality of frames of which the number is a first number, allocating FEC data to the TL, and interleaving at least one of the FEC data and video data constituted of at least one frame for the TL; and a communication section configured to transmit the transmission packet to a client apparatus.

According to a third aspect of the present invention, there is provided a client apparatus for receiving scalable video streaming, including: a communication section configured to receive a scalable video bit-stream constituted of a transmission packet generated by generating a plurality of TLs of which the number is a second number to provide temporal scalability for one GOP constituted of a plurality of frames of which the number is a first number, allocating FEC data to the TL, and interleaving at least one of the FEC data and video data constituted of at least one frame for the TL; and a decoder configured to perform FEC decoding and scalable video decoding in units of TLs included in the scalable video bit-stream.

The client apparatus may further include an encoder configured to perform FEC coding and SVC in units of TLs.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 illustrates an example of an MCTF structure for providing temporal scalability in SVC;

FIG. 2 illustrates an example of a sequence of transmission of scalable video frames based on the MCTF structure illustrated in FIG. 1;

FIG. 3 illustrates an example of an algorithm for allocating FEC packets of scalable video data having a hierarchical structure;

FIG. 4 illustrates an FEC packet structure according to an exemplary embodiment of the present invention;

FIG. 5 illustrates an FEC packet structure according to another exemplary embodiment of the present invention;

FIG. 6 is a block diagram illustrating a configuration of an FEC packet generation apparatus according to an exemplary embodiment of the present invention; and

FIG. 7 is a block diagram illustrating a schematic configuration of a communication system having a server including an FEC packet generation section and a client apparatus.

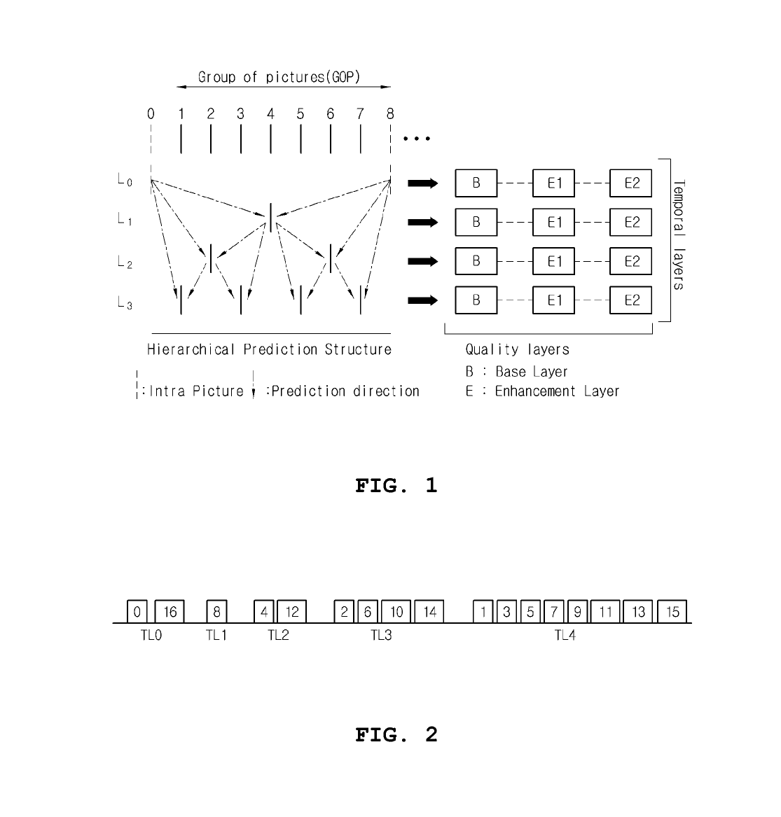

### DETAILED DESCRIPTION OF EXEMPLARY EMBODIMENTS

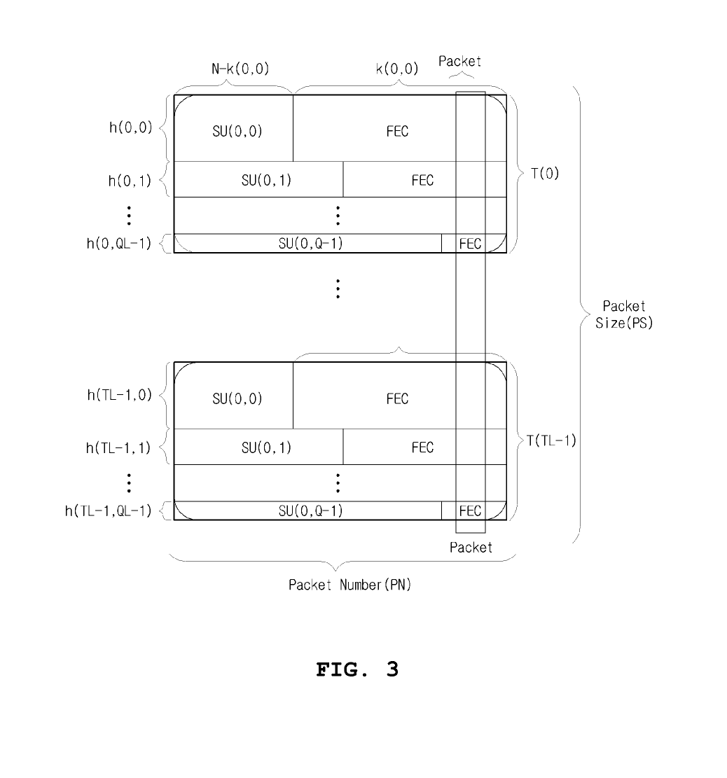

Exemplary embodiments of the present invention will be described in detail below with reference to the accompanying drawings. The same reference numbers are used throughout the drawings to refer to the same or like parts. FIG. 3 illustrates an example of a two-dimensional (2D) FEC allocation algorithm for allocating an FEC packet of scalable video data having a hierarchical structure. Here, T(0) represents TL0, and T(TL−1) represents a TL having a largest TL number, for example, “3” in FIG. 1. SU(t, q) represents a scalable unit (SU) as video data corresponding to QL q in TL t. k(t, q) represents FEC data allocated to QL q in TL t. h(t, q) is a value that is incremented when k(t, q) is allocated for SU(t, q), and constitutes a packet size (PS).

According to the algorithm illustrated in FIG. 3, FEC is differentially allocated according to importance of SU(t, q). Here, the importance of SU(t, q) is determined in consideration of an influence on error propagation when data is lost. In addition, FEC coding is performed for FEC redundancy allocated to SU(t, q).

On the other hand, in order to achieve an advantage of interleaving in the algorithm illustrated in FIG. 3, packets are vertically arranged instead of FEC coded packets being transmitted. It is possible to prevent video data from being lost due to a burst error because packets to be transmitted are vertically arranged as described above.

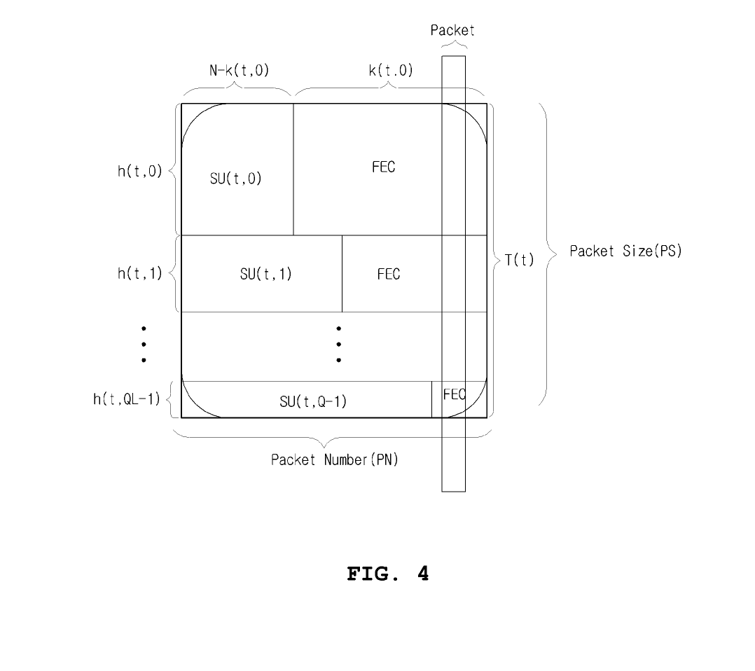

FIG. 4 is a diagram illustrating an FEC packet structure according to an exemplary embodiment of the present invention. It is possible to improve image quality while a delay is minimized when each TL is decoded by allocating FEC data k(t, q) to QL q in TL t. In this case, the PS is identical and a packet number (PN) can be decreased as compared to those of the existing algorithm. When the FEC packet is configured as described above, a delay can be minimized because decoding is possible only if a corresponding TL is received in the scalable video decoder.

Referring to FIG. 4, it can be seen that a size of FEC data allocated to each SU decreases in order from a low SU to a high SU, that is, in order of importance, when a TL is constituted of a plurality of SUs of which the number is a third number.

In the FEC packet structure illustrated in FIG. 4, interleaving is performed between SUs in one TL. In this case, one transmission packet can include FEC data, video data, or both.

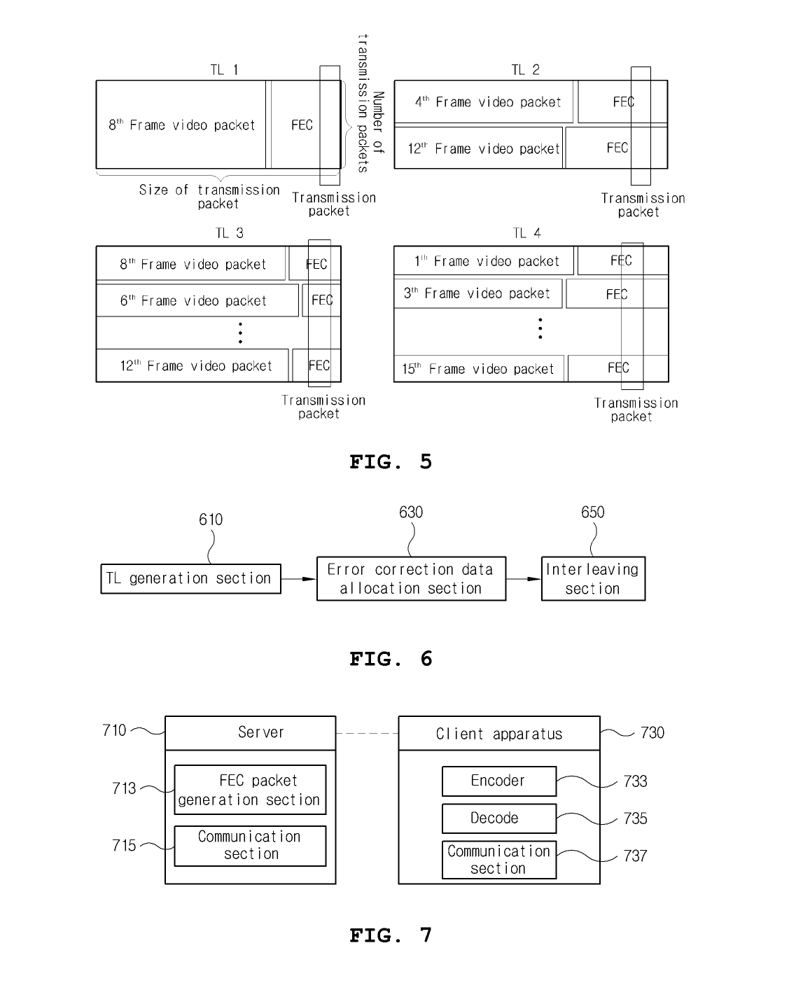

FIG. 5 is a diagram illustrating an FEC packet structure according to another embodiment of the present invention. FEC data is allocated to each TL so that a delay can be minimized during FEC decoding.

Referring to FIG. 5, it can be seen that a size of FEC data allocated to each TL decreases in order from low TL1 to high TL4.

In the FEC packet structure illustrated in FIG. 5, interleaving is performed between FEC data and video data in one TL. In this case, both of FEC data and video data can be included in one transmission packet.

FIG. 6 is a block diagram illustrating a configuration of an FEC packet generation apparatus according to an exemplary embodiment of the present invention. The FEC packet generation apparatus can include a TL generation section 610, an error correction data allocation section 630, and an interleaving section 650. Each component can be integrated into at least one module and implemented by at least one processor (not illustrated).

Referring to FIG. 6, the TL generation section 610 generates a plurality of TLs of which the number is a second number to provide temporal scalability for one GOP constituted of a plurality of frames of which the number is a first number. At this time, MCTF may be preferably applied, but the present invention is not limited thereto.

The error correction data allocation section 630 allocates FEC data to a TL. According to an exemplary embodiment, it is preferable that a size of FEC data allocated to each TL decrease in order from a low TL to a high TL. According to another exemplary embodiment, it is preferable that a size of FEC data allocated to each SU decrease in order from a low SU to a high SU when the TL is constituted of a plurality of SUs of which the number is a third number.

The interleaving section 650 generates a transmission packet by interleaving at least one of FEC data and video data configured in at least one frame for a TL. According to an exemplary embodiment, it is possible to generate a transmission packet by interleaving FEC data and video data configured in at least one frame for each TL. According to another exemplary embodiment, it is possible to generate a transmission packet by performing interleaving among a plurality of SUs for each TL.

FIG. 7 is a diagram illustrating a schematic configuration of a communication system having a server including an FEC packet generation section and a client apparatus according to an exemplary embodiment of the present invention. The server 710 can include an encoder, which includes the FEC packet generation section 713, and a communication section 715. The client apparatus 730 can include at least one of an encoder 733 and a decoder 735, and a communication section 737. Here, the server 710 can further include a memory (not illustrated) that stores a scalable video bit-stream. An example of the client apparatus may be a broadcast reception apparatus including a mobile terminal, a television (TV), an MPEG-1 Audio Layer 3 (MP3) player, or the like, but the present invention is not limited thereto.

Referring to FIG. 7, in the server 710, the FEC packet generation section 713 generates a transmission packet by generating a plurality of TLs of which the number is a second number to provide temporal scalability for one GOP constituted of a plurality of frames of which the number is a first number, allocating FEC data for the TL, and interleaving at least one of the FEC data and video data constituted of at least one frame for the TL.

The communication section 715 can transmit a bit-stream including the transmission packet provided from the FEC packet generation section 713 to the client apparatus or can be provided to an external device for storage.

The communication section 715 is configured to transmit and receive data to and from an external multimedia device over a wireless network such as wireless Internet, a wireless intranet, a wireless telephone network, a wireless local area network (LAN), a wireless fidelity (Wi-Fi) network, a Wi-Fi Direct (WED) network, a third generation (3G) network, a fourth generation (4G) network, a Bluetooth network, an infrared data association (IrDA) network, a radio frequency identification (RFID) network, an ultra wideband (UWB) network, a Zigbee network, or a near field communication (NFC) network, a wired telephone network, or a wired network such as wired Internet.

On the other hand, in the client apparatus 730, the encoder 733 generates a scalable video bit-stream by performing FEC coding and SVC in units of TLs.

The decoder 735 performs FEC decoding and scalable video decoding in units of TLs included in a received scalable video bit-stream.

The communication section 737 receives a scalable video bit-stream constituted of a transmission packet generated by generating a plurality of TLs of which the number is a second number to provide temporal scalability for one GOP constituted of a plurality of frames of which the number is a first number, allocating FEC data to the TL, and interleaving at least one of the FEC data and video data constituted of at least one frame for the TL. The communication section 737 of the client apparatus 730 can be configured to be similar to the communication section 715 of the server 710.

According to another exemplary embodiment, an encoder can be provided within the server 710, and a decoder can be provided within the client apparatus 730. According to still another exemplary embodiment, the client apparatus can be provided with both the encoder and the decoder.

The method according to the above-described exemplary embodiment can be implemented by a computer-executable program, and implemented in a general-purpose digital computer that operates the program using a computer-readable recording medium. A data structure, a program command, or a data file usable in the above-described exemplary embodiments can be recorded on computer-readable recording media through various means. The computer-readable recording media can include all types of storage devices in which data readable by a computer system is stored. For example, the computer-readable media may include magnetic media such as a hard disk, a floppy disk and magnetic tape, optical media such as a compact disc read-only memory (CD-ROM) and a digital versatile disc (DVD), magneto-optical media such as floptical disc, and hardware devices such as a ROM, a random access memory (RAM), and a flash memory particularly implemented to store and execute program commands. In addition, the computer-readable recording media may be transmission media for delivering signals indicating program commands, data structures, and the like. For example, the program commands may be machine language codes produced by a compiler and/or high-level language codes that can be executed by computers using an interpreter and the like.

According to the present invention, it is possible to perform FEC without receiving all data by allocating FEC data in units of TLs, and hence minimize a delay. In addition, there is an advantage in that robustness to burst errors is provided by applying interleaving between video data and FEC data for the TLs.

A method of generating an FEC packet and a server and a client apparatus using the same according to the present invention described above are not limited to the above-described exemplary embodiments. It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A method of generating a forward error correction (FEC) packet, comprising:
generating a plurality of temporal layers (TLs) of which the number is a second number to provide temporal scalability for one group of pictures (GOP) constituted of a plurality of frames of which the number is a first number;
allocating FEC data to the TL; and
generating a transmission packet by interleaving at least one of the FEC data and video data constituted of at least one frame for the TL.

2. The method of claim 1, wherein the plurality of TLs of which the number is the second number are generated by motion compensated temporal filtering (MCTF).

3. The method of claim 1, wherein a size of the FEC data to the TL decreases in order from a low TL to a high TL.

4. The method of claim 1, wherein, when the TL is constituted of a plurality of scalable units (SUs) of which the number is a third number, a size of FEC data allocated to each SU decreases in order from a low SU to a high SU.

5. The method of claim 1, wherein, when each TL is constituted of video data and a plurality of SUs of which the number is a third number constituted of quality data corresponding to the video data, the transmission packet is generated by performing interleaving among a plurality of SUs.

6. A server for providing scalable video streaming, comprising:
an FEC packet generation section configured to generate a transmission packet by generating a plurality of TLs of which the number is a second number to provide temporal scalability for one GOP constituted of a plurality of frames of which the number is a first number, allocating FEC data to the TL, and interleaving at least one of the FEC data and video data constituted of at least one frame for the TL; and
a communication section configured to transmit the transmission packet to a client apparatus.

7. A client apparatus comprising:
a communication section configured to receive a scalable video bit-stream constituted of a transmission packet generated by generating a plurality of TLs of which the number is a second number to provide temporal scalability for one GOP constituted of a plurality of frames of which the number is a first number, allocating FEC data to the TL, and interleaving at least one of the FEC data and video data constituted of at least one frame for the TL; and
a decoder configured to perform FEC decoding and scalable video decoding in units of TLs included in the scalable video bit-stream.

8. The client apparatus of claim 7, further comprising:
an encoder configured to perform FEC coding and scalable video coding in units of TLs.
